(19) United States
(12) Patent Application Publication
(10) Pub. No.: US 2017/0309684 A1
(43) Pub. Date: Oct. 26, 2017

(54) PHOTOELECTRIC CONVERSION DEVICE AND IMAGING SYSTEM

(71) Applicant: CANON KABUSHIKI KAISHA, Tokyo (JP)

(72) Inventors: Naoki Yamada, Inagi-shi (JP); Hidekazu Takahashi, Zama-shi (JP); Yojiro Matsuda, Kawasaki-shi (JP); Tetsuo Takahashi, Kawasaki-shi (JP); Hirokazu Miyashita, Tokyo (JP); Masumi Itabashi, Yamato-shi (JP); Kazuaki Tashiro, Isehara-shi (JP)

(21) Appl. No.: 15/492,904

(22) Filed: Apr. 20, 2017

(30) Foreign Application Priority Data
Apr. 25, 2016 (JP) 2016-087316
Jul. 5, 2016 (JP) 2016-133394
Feb. 28, 2017 (JP) 2017-037708

(51) Int. Cl. H01L 27/30; H01L 51/44

(52) U.S. Cl. CPC H01L 27/307; H01L 51/44

(57) ABSTRACT

The present disclosure provides a photoelectric conversion device including a semiconductor substrate including a signal output portion, an electrode, and an organic compound layer disposed between the signal output portion and the electrode and including a photoelectric conversion layer, wherein the signal output portion is in contact with the organic compound layer.

### BACKGROUND OF THE INVENTION

### Field of the Invention

The present disclosure relates to a photoelectric conversion device and an imaging system using a photoelectric conversion device.

### Description of the Related Art

A photoelectric conversion device is a device for converting the energy of received light into electrical energy. An imaging apparatus using these devices arranged two-dimensionally for an image sensor is known. Japanese Patent Application Laid-Open No. 2015-119018 discusses an imaging apparatus including a photoelectric conversion layer formed using a chalcopyrite-based inorganic material, and a dark current suppression layer including a non-chalcopyrite-based inorganic material placed between the photoelectric conversion layer and a charge accumulation layer.

In the imaging apparatus discussed in Japanese Patent Application Laid-Open No. 2015-119018, the photoelectric conversion layer includes a chalcopyrite-based inorganic material forming a crystal state, thereby heightening the photoelectric conversion efficiency. However, there is a need to further improve the photoelectric conversion efficiency.

### SUMMARY OF THE INVENTION

The present disclosure is directed to providing a photoelectric conversion device that includes an organic compound layer including a photoelectric conversion layer and does not include an electrode between the organic compound layer and a charge accumulation portion, thereby reducing thermal noise (kTC noise) generated when the photoelectric conversion device is reset, and having high photoelectric conversion efficiency.

According to an aspect of the present disclosure, a photoelectric conversion device includes a semiconductor substrate including a charge accumulation portion, an organic compound layer including a photoelectric conversion layer, and an electrode in this order, and the charge accumulation portion is in contact with the organic compound layer.

Further features of the present disclosure will become apparent from the following description of exemplary embodiments with reference to the attached drawings.

### BRIEF DESCRIPTION OF THE DRAWINGS

FIG. 1 is a schematic cross-sectional view of an example of a photoelectric conversion device.

FIG. 2 is a circuit diagram of an example of a pixel including the photoelectric conversion device.

FIG. 3 is a diagram illustrating an example of an image sensor.

FIG. 4 is a schematic cross-sectional view of an example of the photoelectric conversion device.

FIG. 5 is a schematic cross-sectional view of a photoelectric conversion element according to an exemplary embodiment.

### DESCRIPTION OF THE EMBODIMENTS

A photoelectric conversion device includes a semiconductor substrate including a charge accumulation portion, an organic compound layer including a photoelectric conversion layer, and an electrode in this order. The charge accumulation portion and the organic compound layer are in contact with each other, thereby reducing noise. The photoelectric conversion layer is an organic compound, thereby having high photoelectric conversion efficiency. It is desirable that the organic compound layer should be in an amorphous state. Further, it is desirable that the organic compound layer should not have a crystal defect level. The organic compound layer does not have a crystal defect level, whereby it is possible to suppress dark current in the photoelectric conversion element.

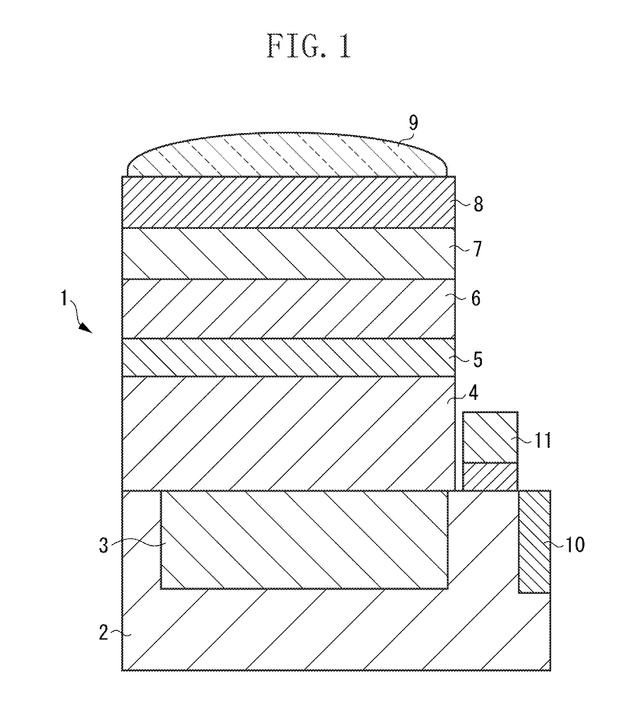

FIG. 1 is a schematic cross-sectional view illustrating an example photoelectric conversion device n. A photoelectric conversion device 1 includes a semiconductor substrate 2, which includes a charge accumulation portion 3, an organic compound layer 4, which includes a photoelectric conversion layer, an electrode 5, a protection layer 6, a planarizing layer 7, a wavelength selection portion 8, and a microlens 9. The photoelectric conversion device 1 may be connected to a reading circuit including floating diffusion (hereinafter “FD”) 10 and a gate electrode 11.

The organic compound layer 4 at least includes a photoelectric conversion layer and may further include a charge transport layer. The organic compound layer 4 may include a first charge transport layer between the charge accumulation portion 3 and the photoelectric conversion layer and include a second charge transport layer between the photoelectric conversion layer and the electrode 5.

The photoelectric conversion layer and the charge transport layer may include a single compound or a plurality of materials. For example, the photoelectric conversion layer may include a charge separation material.

It is desirable that the organic compound layer 4 should be an amorphous. To facilitate the formation of an amorphous, it is desirable that the glass-transition temperature should be 80° C. or more. It is more desirable that the glass-transition temperature should be 100° C. or more. The glass-transition temperature can be measured by a known method such as differential scanning calorimetry analysis.

It is desirable that the layer thickness of each layer included in the organic compound layer 4 should enable the formation of a stable amorphous layer. Specifically, it is desirable that the thickness of the charge transport layer should be 10 nm or more. Meanwhile, it is desirable that the layer thickness should be small to reduce the driving voltage. It is desirable that the layer thickness of the photoelectric conversion layer should enable sufficient absorption of incident light. Specifically, it is desirable that the thickness of the photoelectric conversion layer should be 50 nm or more. Meanwhile, it is desirable that the layer thickness should be small to reduce the driving voltage.

It is desirable that the absorption coefficient of the organic compound layer 4 should be high. The absorption coefficient is high, whereby it is possible to make the layer thickness of the photoelectric conversion layer small even with the same sensitivity. As a result, it is possible to reduce the driving voltage.

The organic compound layer 4 can be formed using a vapor deposition method such as a vacuum deposition method or an application method such as a spin coating method.

The charge transport layer may be provided between the photoelectric conversion layer and the charge accumulation portion 3 or provided between the photoelectric conversion layer and the electrode 5. It is desirable that the performance of the charge transport layer transporting a hole or an electron should be high. The charge transport layer may function as a charge blocking layer or an adhesion layer for the semiconductor layer.

In a case where a hole is accumulated in the charge accumulation portion 3, it is desirable that the lowest unoccupied molecular orbital (LUMO) energy level of the charge transport layer between the charge accumulation portion 3 and the photoelectric conversion layer should be low. Specifically, it is desirable that the LUMO energy level should be lower than 4.5 eV. It is more desirable that the LUMO energy level should be lower than 3.5 eV. Examples of such a compound include an amine compound, a carbazole compound, and derivatives of these compounds.

The reason why it is desirable that the LUMO energy level should be low is as follows. To suppress dark current, it is desirable that the LUMO should be lower in energy level than the conduction band of the layer in contact with the charge transport layer. Consequently, it is possible to inhibit the movement of an electron from the charge accumulation portion 3 to the organic compound layer 4. As a result, it is possible to suppress dark current. The charge transport layer in this case is occasionally referred to as an “electron blocking layer”.

Further, in a case where a hole is accumulated in the charge accumulation portion 3, it is desirable that the highest occupied molecular orbital (HOMO) energy level of the charge transport layer between the photoelectric conversion layer and the electrode 5 should be high. Specifically, it is desirable that the HOMO energy level should be higher than 5.0 eV. It is more desirable that the HOMO energy level should be higher than 5.5 eV. Examples of such a compound include a fullerene compound, a phenanthroline compound, and derivatives of these compounds.

The reason why it is desirable that the HOMO energy level should be high is as follows. To suppress dark current, it is desirable that the HOMO should be higher in energy level than the valence band of the layer, including an electrode, in contact with the charge transport layer. Consequently, it is possible to inhibit the movement of a hole from the electrode 5 to the organic compound layer 4. As a result, it is possible to suppress dark current. The charge transport layer in this case is occasionally referred to as a “hole blocking layer”.

On the other hand, in a case where an electron is accumulated in the charge accumulation portion 3, the charge transport layer between the charge accumulation portion 3 and the photoelectric conversion layer is a hole blocking layer, and the charge transport layer between the photoelectric conversion layer and the electrode 5 is an electron blocking layer.

The HOMO energy level of the organic compound or the valence band level of the charge accumulation portion 3 can be obtained by measuring the ionization potential by ultraviolet photoelectron spectroscopy or atmospheric photoelectron spectroscopy.

The LUMO energy level of the organic compound or the conduction band level of the charge accumulation portion 3 can be obtained from the relationships between the HOMO energy level and the valence band level, and the optical band gap. Alternatively, the LUMO energy level of the organic compound or the conduction band level of the charge accumulation portion 3 can also be measured by inverse photoelectron spectroscopy. The band gap can be obtained from the ends of the absorption spectrum.

The state where the HOMO energy level or the LUMO energy level is high refers to the state where the absolute value of the HOMO energy level or the LUMO energy level is large. Further, the state where the HOMO energy level or the LUMO energy level is high can also be represented as the state where the HOMO energy level or the LUMO energy level is deep. The higher the HOMO energy level or the LUMO energy level, the further away from the vacuum level.

The HOMO, the LUMO, and the band gap of the charge transport layer can have, as the values of the charge transport layer, the HOMO, the LUMO, and the band gap of a compound having the largest composition ratio in the charge transport layer.

At the interface at which the organic compound layer 4 is in contact with the charge accumulation portion 3, the organic compound layer 4 may form a chemical bond with an atom included in the charge accumulation portion 3. The organic compound and the atom included in the charge accumulation portion 3 are chemically bonded together, thereby reducing a dangling bond in the charge accumulation portion 3. As a result, it is possible to reduce noise resulting from the dangling bond. Further, it is considered that this promotes the injection of a charge from the organic compound into the charge accumulation portion 3.

The configuration may be such that the atom included in the charge accumulation portion 3 and a part of the organic compound at the interface of the organic compound layer 4 are chemically bonded together.

In a case where the atom included in the charge accumulation portion 3 is Si, examples of the above chemical bond include the following.

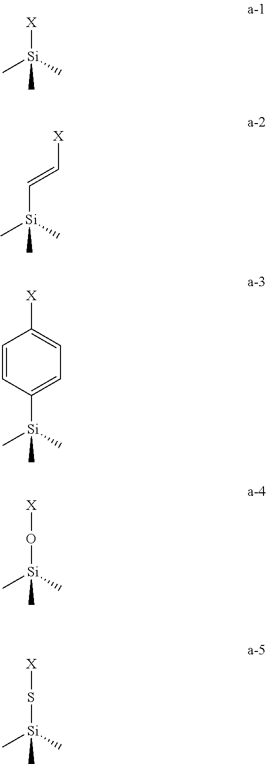

“X” represents the organic compound included in the organic compound layer 4, and “Si” represents the Si atom in the charge accumulation portion 3. Examples of the form of the chemical bond between X and Si include a covalent bond (a-1), a vinylene group (a-2), an aryl group or a heteroaryl group (a-3), an oxygen atom (a-4), and a sulfur atom (a-5). In the chemical bond, the organic compound may be directly bonded to the Si atom. In the structures of a-2 and a-3, X and Si are bonded together in a conjugated manner. Thus, it is considered that this further promotes the performance of injecting a carrier into Si. Si and X are bonded together by acidic treatment using HF.

Although the film thickness of the charge transport layer is not particularly defined, it is desirable that the film thickness should enable the formation of a stable amorphous film. It is desirable that the thickness of the charge transport layer should be 10 nm or more. Meanwhile, it is desirable that the film thickness should be small, because it is possible to reduce the driving voltage.

Examples of the organic compound included in the electron blocking layer include the following, but are not limited to these.

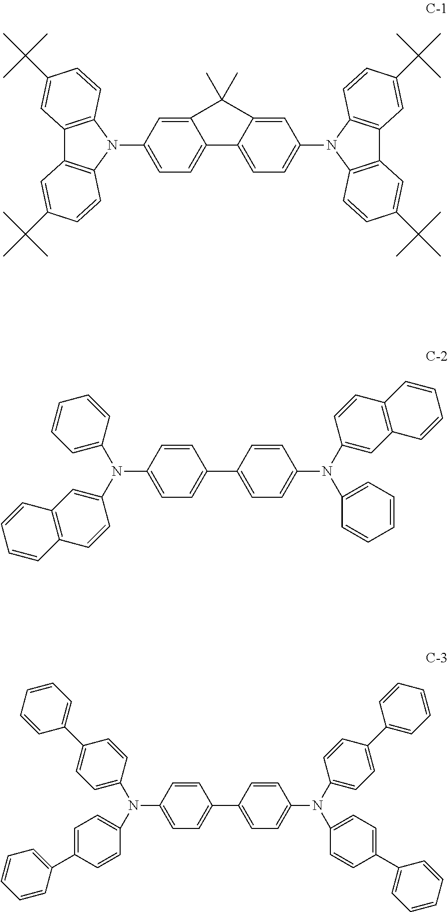 [SMILES: CC(C)(C)c1ccc2c(c1)c1cc(C(C)(C)C)ccc1n2-c1ccc2c(c1)C(C)(C)c1cc(-n3c4ccc(C(C)(C)C)cc4c4cc(C(C)(C)C)ccc43)ccc1-2 ; c1ccc(N(c2ccc(-c3ccc(N(c4ccccc4)c4ccc5ccccc5c4)cc3)cc2)c2ccc3ccccc3c2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1]

Examples of the organic compound included in the hole blocking layer include the following, but are not limited to these.

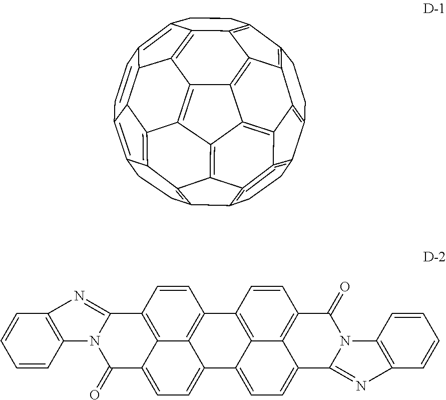

Examples of the organic compound bonded to the Si atom in the charge accumulation portion 3 include the following, but are not limited to these.

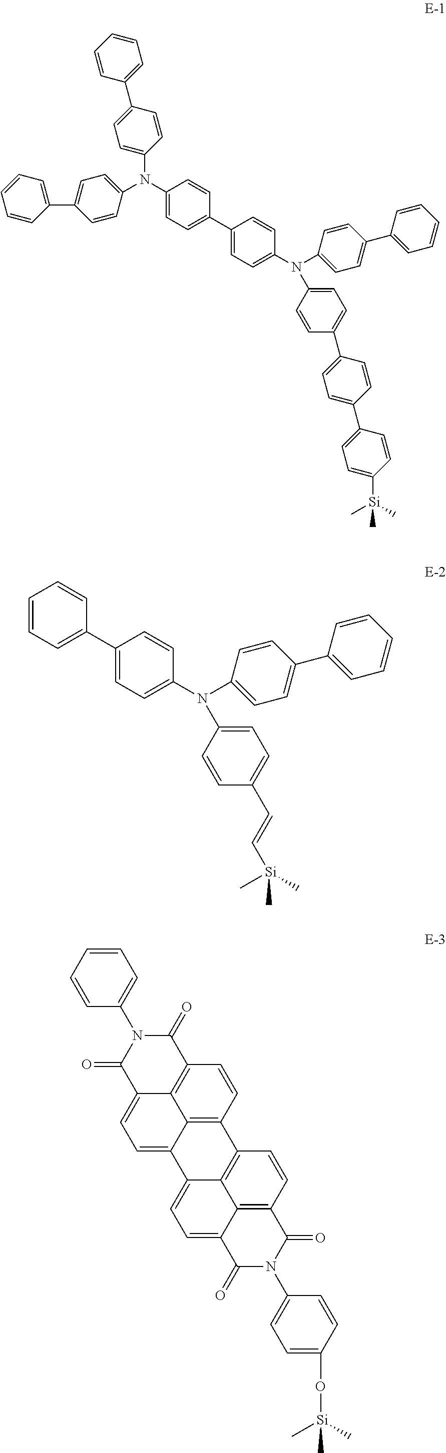

The photoelectric conversion layer may include a fullerene compound such as a C60 derivative or a C70 derivative, a phthalocyanine compound, a carboxylic acid diimide compound, a metal complex compound, a squarylium compound, a merocyanine compound, an azo compound, an aromatic amine compound, a condensed polycyclic compound, a condensed heteropolycyclic compound, a heterocyclic compound, or a polymeric compound such as polythiophene.

The photoelectric conversion layer may include a single compound or a plurality of compounds among these compounds. In a case where the photoelectric conversion layer includes a plurality of compounds, it is possible to appropriately set the mixing ratio of the plurality of compounds.

Further, the photoelectric conversion layer may include a plurality of layers. In a case where a plurality of layers is laminated, it is possible to appropriately set the film thickness ratio of the plurality of layers.

To obtain a photoelectric conversion layer having high photoelectric conversion efficiency, it is desirable to use a compound having high electron-withdrawing properties and a compound having high electron-donating properties by laminating or mixing these compounds. The compound having high electron-withdrawing properties can be referred to as an “electron-withdrawing compound”, and the compound having high electron-donating properties can be referred to as an “electron-donating compound”.

Examples of the compound having high electron-withdrawing properties include a fullerene compound such as a C60 derivative or a C70 derivative, a metal complex compound, a phthalocyanine compound, and a carboxylic acid diimide compound. Among these compounds, the fullerene compound such as a C60 derivative or a C70 derivative is desirable.

In this case, a derivative includes a compound including a substituent group in its basic structure. For example, the C60 derivative may be a compound in which C60 includes a substituent group. Examples of the substituent group include an alkyl group, an aryl group, and a heterocyclic group. A carbon atom of the alkyl group may be replaced by a carbonyl group or a carboxyl group, except for the structure in which successive carbon atoms are all replaced by carbonyl groups or carboxyl groups. The aryl group and the heterocyclic group may further include an alkyl group as a substituent group.

Examples of the compound having high electron-withdrawing properties include the following, but are not limited to these.

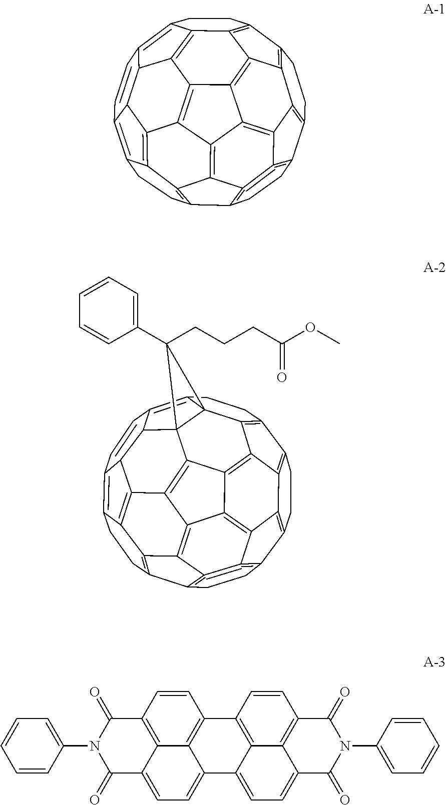

Examples of the compound having high electron-donating properties include a phthalocyanine compound, a metal complex compound, a squarylium compound, a merocyanine compound, an azo compound, an aromatic amine compound, a condensed polycyclic compound, a condensed heteropolycyclic compound, a heterocyclic compound, and a polymeric compound such as polythiophene. Examples of the compound having high electron-donating properties include the following, but are not limited to these. In each structural formula, represents the degree of polymerization and is an integer equal to or greater than 2.

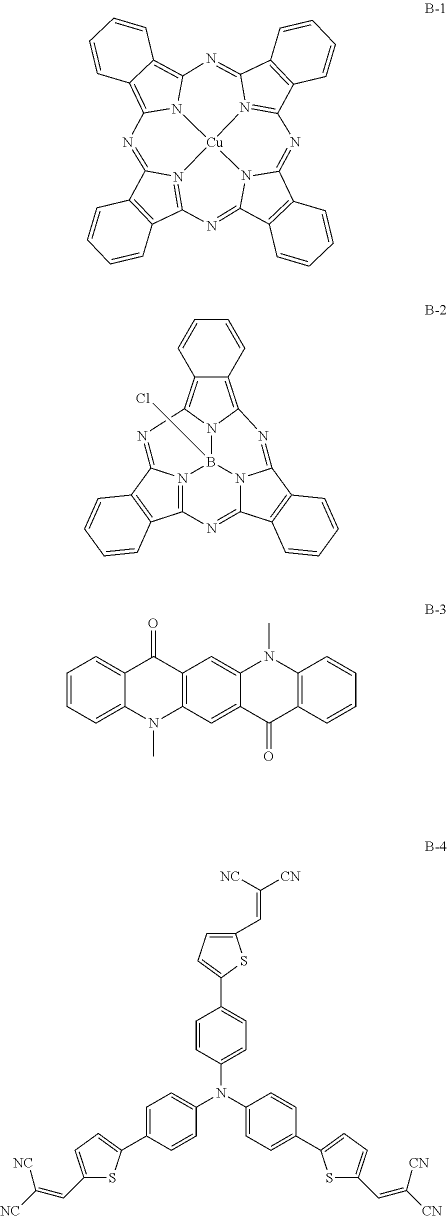

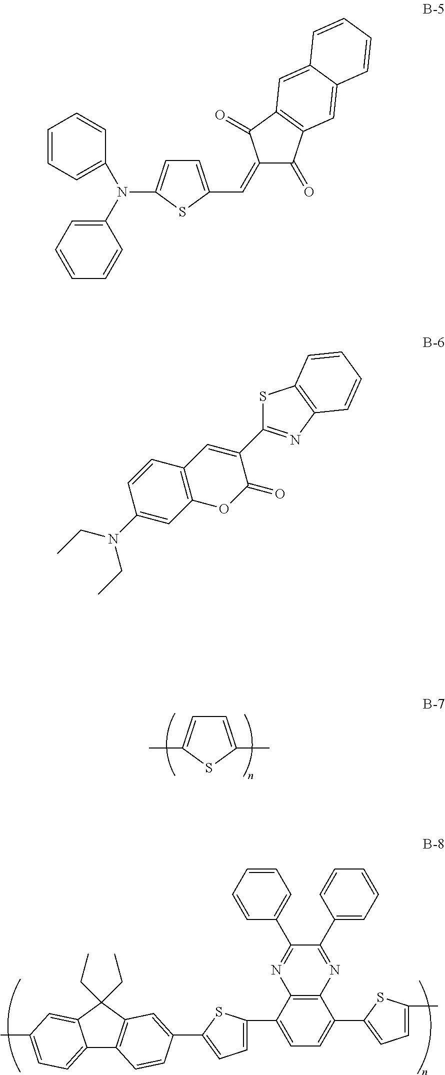

The constituent element of the semiconductor substrate 2 is not limited so long as the constituent element can form the charge accumulation portion 3 and the FD 10 by implanting impurities into the constituent element. Examples of the constituent element include Si, GaAs, and GaP. Si is particularly desirable.

The semiconductor substrate 2 may be an n-type epitaxial layer. In this case, a p-type well, an n-type well, a p-type semiconductor region, and an n-type semiconductor region are disposed in the semiconductor substrate 2.

A signal output portion 3 outputs a charge signal to outside the device. The signal output portion 3 may output a photoelectrically converted charge as it is, or may accumulate and transfer a charge. In a case where a charge is accumulated, the signal output portion 3 includes a charge accumulation portion. The charge accumulation portion is an n-type semiconductor region or a p-type semiconductor region formed in the semiconductor substrate 2 by implanting ions, and is a region where a charge generated in a photoelectric conversion portion is accumulated. Hereinafter, the configuration in which the signal output portion 3 includes a charge accumulation portion is exemplified.

In a case where an electron is accumulated, an n-type semiconductor region may be formed on the surface of the semiconductor substrate 2, or an accumulation diode having a p-n structure may be formed from the surface of the substrate 2. In either case, an electron can be accumulated in an n-type semiconductor region.

On the other hand, in a case where a hole is accumulated, a p-type semiconductor region may be formed on the semiconductor substrate 2, or an accumulation diode having an n-p structure may be formed from the surface of the substrate 2. In either case, a hole can be accumulated in a p-type semiconductor region.

The accumulated charge is transferred from the charge accumulation portion 3 to the FD 10. This transfer of the charge may be controlled by the gate electrode 11. A charge generated in the organic compound layer 4 is accumulated in the charge accumulation portion 3, and the charge accumulated in the charge accumulation portion 3 is transferred to the FD 10. Then, the charge is converted into a current by an amplification transistor 14.

Further, in a case where the charge accumulation portion 3 forms a p-n junction, light leaking from the photoelectric conversion portion may be photoelectrically converted.

The electrode 5 is referred to also as an “upper electrode”. It is desirable that the electrode 5 should be made of a transparent conductive material. Examples of the transparent conductive material include indium tin oxide (ITO), indium zinc oxide (IZO), and a conductive organic material. The transparent conductive material is not limited to the above examples so long as the transparent conductive material can transmit light. For example, a thin film may be formed of silver, magnesium, or an alloy of these. The electrode 5 can be formed by a known method such as a sputtering method or a vapor deposition method.

Photoelectric conversion layers, functional layers, and electrodes of a plurality of photoelectric conversion elements may be collectively formed or individually formed by a vacuum deposition method or an application method.

The protection layer 6 is a layer formed over the electrode 5. It is desirable that the protection layer 6 should be an insulating layer. The protection layer 6 may be formed of a single material or may include a plurality of materials. In a case where the protection layer 6 includes a plurality of materials, a plurality of layers may be laminated, or a layer may be formed by mixing a plurality of materials. Examples of the constituent material of the protection layer 6 include an organic material such as a resin and an inorganic material such as SiNx, SiOx, and Al₂O₃. “x” is a numerical value indicating the ratio of the element.

The planarizing layer 7 is provided over the protection layer 6. The planarizing layer 7 is provided to prevent the wavelength selection portion 8 from being influenced by the surface state of the protection layer 6. The planarizing layer 7 may not be provided depending on the surface state of the protection layer 6. The planarizing layer 7 can be formed by a known manufacturing method, a known application method, or a known vacuum deposition method. The planarizing layer 7 may be manufactured by performing chemical mechanical polishing (CMP), where necessary. Examples of the constituent material of the planarizing layer 7 include an organic material such as a resin and an inorganic material such as SiNx, SiOx, and Al₂O₃. The planarizing layer 7 may include an organic compound or a mixture of organic compounds.

The wavelength selection portion 8 is provided over the planarizing layer 7. In a case where the planarizing layer 7 is not included, the wavelength selection portion 8 is provided over the protection layer 6. The wavelength selection portion 8 can also be placed on the light incident side of the photoelectric conversion element 1.

Examples of the wavelength selection portion 8 include a color filter, a scintillator, and a prism.

A color filter is a filter for transmitting more light of a predetermined wavelength than light of another wavelength. For example, it is possible to cover the entire range of visible light using three types of color filters, namely red, green, and blue (RGB) filters. In a case where the three types of color filters, namely RGB filters, are used, the color filters may be placed using the Bayer arrangement.

Alternatively, the wavelength selection portion 8 may be a prism for separating only light of a predetermined wavelength.

Yet alternatively, the wavelength selection portion 8 may have the function of converting light of a predetermined wavelength into light of another wavelength as in a scintillator.

The position where the wavelength selection portion 8 is disposed is not limited to the position illustrated in FIG. 1. The wavelength selection portion 8 may be disposed at any position on an optical path from an object or a light source to the photoelectric conversion layer 4.

The microlens 9 is an optical member for collecting light from outside the device onto the photoelectric conversion layer. Although FIG. 1 illustrates an example of a lens having a hemispherical shape, the shape of the microlens 9 is not limited to this. The microlens 9 includes, for example, quartz, silicon, or an organic resin. The shape and the material of the microlens 9 are not limited so long as the collection of light is not hindered.

The photoelectric conversion element 1 may include another photoelectric conversion element above the electrode 5. Another photoelectric conversion element is used as a photoelectric conversion element for photoelectrically converting light of a different wavelength, whereby it is possible to detect light of different wavelengths at the same position or almost the same position in the surface on the substrate 2.

Further, a different type of organic compound layer for photoelectrically converting light of a different wavelength from the organic compound layer 4 may be further included, and the organic compound layer 4 and the different type of organic compound layer may be laminated. With this configuration, similarly to the configuration in which photoelectric conversion elements are laminated, it is possible to detect light of different wavelengths at the same position or almost the same position on the substrate 2.

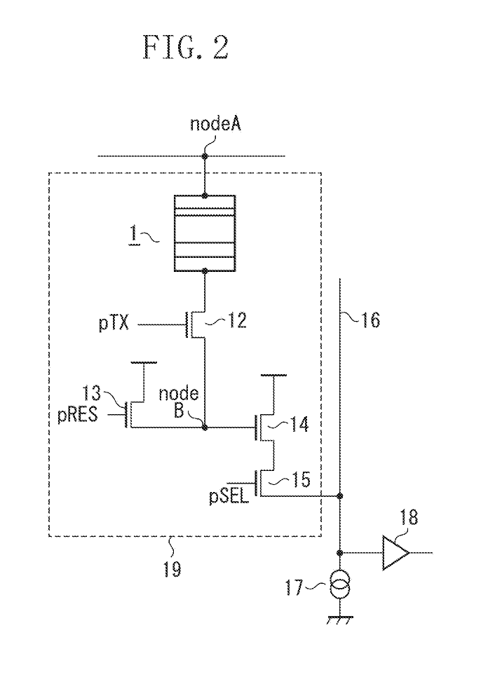

FIG. 2 is a circuit diagram of an example pixel including the photoelectric conversion device. The photoelectric conversion device 1 is connected to common wiring at a node A. The common wiring may be connected to the ground.

A pixel 19 may include the photoelectric conversion element 1 and a reading circuit for reading a signal generated in a photoelectric conversion portion. The reading circuit may include, for example, a transfer transistor 12, which is electrically connected to the photoelectric conversion element 1, an amplification transistor 14, which includes a gate electrode electrically connected to the photoelectric conversion element 1, a selection transistor 15, which selects a pixel from which information is to be read, and a reset transistor 13, which supplies a reset voltage to the photoelectric conversion element 1.

The transfer of the transfer transistor 12 may be controlled by a driving pulse pTX. The supply of a voltage from the reset transistor 13 may be controlled by a driving pulse pRES. The selection transistor 15 enters a selected or non-selected state by a driving pulse pSEL.

The transfer transistor 12, the amplification transistor 14, and the reset transistor 13 are connected together at a node B. The transfer transistor 12 may not be included depending on the configuration.

The reset transistor 13 is a transistor for supplying a voltage for resetting the potential of the node B. The driving pulse pRES is applied to the gate of the reset transistor 13, whereby it is possible to control the supply of a voltage. The reset transistor 13 may not be included depending on the configuration.

The amplification transistor 14 is a transistor for carrying a current according to the potential of the node B. The amplification transistor 14 is connected to the selection transistor 15, which selects a pixel from which a signal is to be output. The selection transistor 15 is connected to a current source 17 and a column output circuit 18. The column output circuit 18 may be connected to a signal processing unit.

The selection transistor 15 is connected to a vertical output signal line 16. The vertical output signal line 16 is connected to the current source 17 and the column output circuit 18. The column output circuit 18 may be connected to a signal processing unit.

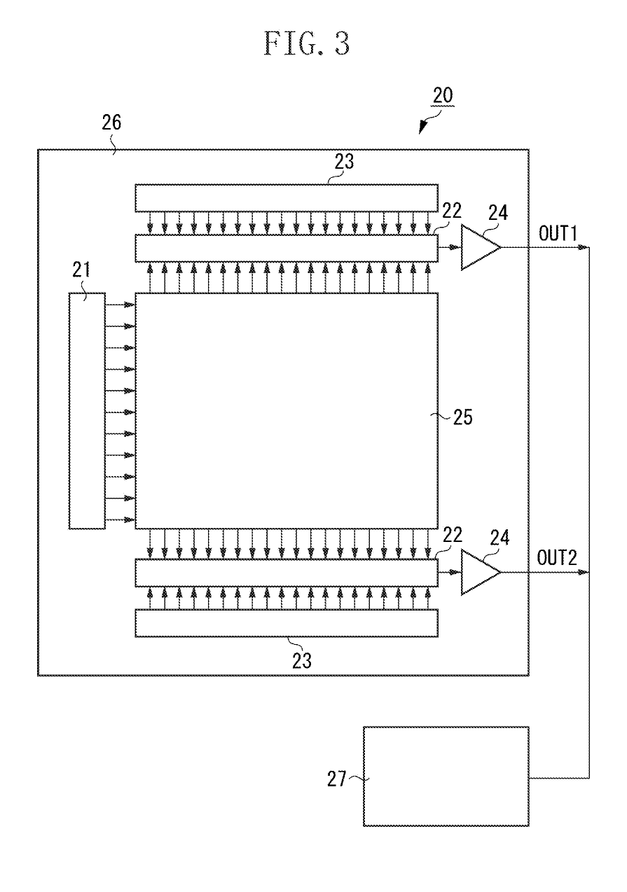

FIG. 3 is a diagram illustrating an example image sensor. An image sensor 20 includes an imaging region 25, where a plurality of pixels is placed two-dimensionally, and a peripheral region 26. A region other than the imaging region 25 is the peripheral region 26. The peripheral region 26 includes a vertical scanning circuit 21, reading circuits 22, horizontal scanning circuits 23, and output amplifiers 24. The output amplifiers 24 are connected to a signal processing unit 27. The signal processing unit 27 is a signal processing unit for performing signal processing based on information read by the reading circuits 22. Examples of the signal processing unit 27 include a charge-coupled device (CCD) circuit and a complementary metal-oxide-semiconductor (CMOS) circuit.

The reading circuits 22 include, for example, a column amplifier, a correlated double sampling (CDS) circuit, and an addition circuit and perform amplification and addition on a signal read via a vertical signal line from a pixel of a row selected by the vertical scanning circuit 21. The column amplifier, the CDS circuit, and the addition circuit are placed, for example, for each pixel column or every plurality of pixel columns. The CDS circuit is a circuit for performing CDS signal processing and reduces kTC noise. The horizontal scanning circuits 23 generate signals for reading signals of the reading circuits 22 in order. The output amplifiers 24 amplify and output a signal of a column selected by the horizontal scanning circuits 23.

The above configuration is merely an example of the configuration of the photoelectric conversion device, and the present exemplary embodiment is not limited to this. The reading circuits 22, the horizontal scanning circuits 23, and the output amplifiers 24 form two different output channels. Thus, the reading circuits 22 are placed one above the other across the imaging region 25, the horizontal scanning circuits 23 are placed one above the other across the imaging region 25, and the output amplifiers 24 are placed one above the other across the imaging region 25. Alternatively, three or more output channels may be provided. Signals output from the respective output amplifiers are combined into an image signal by the signal processing unit 27.

The image may include a plurality of organic compound layers. The image sensor may include an interlayer insulating layer between each pair of the plurality of organic compound layers. The material of the interlayer insulating layer is not limited so long as the interlayer insulating layer is an insulator. It is desirable that the interlayer insulating layer should be an inorganic substance such as SiO2 or an organic substance such as polyimide. Further, the insulating layer may be placed to be inclined with respect to a substrate.

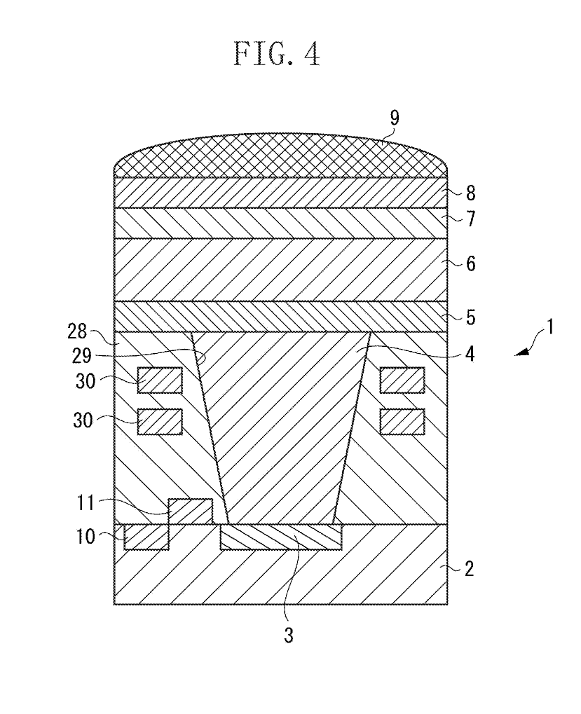

FIG. 4 is a schematic cross-sectional view of a photoelectric conversion element. Members similar to those in FIG. 1 are represented by the same numerals. An interlayer insulating layer 28 separates a photoelectric conversion layer from another photoelectric conversion layer adjacent to the photoelectric conversion layer. Wiring 30 is provided within the interlayer insulating layer 28. The interlayer insulating layer 28 may be provided to be inclined with respect to a substrate 2. With a sloping surface 29, it is possible to efficiently photoelectrically convert also light having an angle of incidence other than 0 degrees. The angle of incidence perpendicular to the substrate 2 is 0 degrees.

The organic compound layer 4 is placed such that the height of the organic compound layer 4 from the substrate 2 is equal to or greater than the height of the interlayer insulating layer 28 from the substrate 2. The photoelectric conversion element is designed such that the distance from the substrate 2 to the photoelectric conversion layer is equal to or greater than the distance from the substrate 2 to the interlayer insulating layer 28, whereby it is possible to obtain a photoelectric conversion element having high stability. More specifically, the yield is improved. The distance from the substrate 2 to each layer is estimated at the point furthest away from the substrate 2 in the layer. In the photoelectric conversion device, the distance from the substrate 2 to each layer can be estimated using cross-sectional scanning electron microscopy (SEM). The measurement method is not limited to cross-sectional SEM, and a known method can be used.

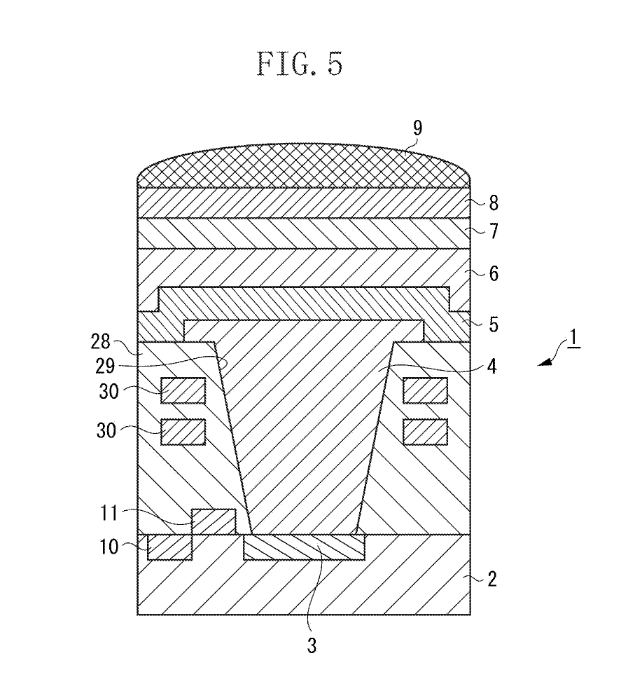

FIG. 5 is a schematic cross-sectional view of a photoelectric conversion element. FIG. 5 is similar to FIG. 4, except that the height of the organic compound layer 4 from a substrate 2 is greater than the height of an interlayer insulating layer 28 from the substrate 2.

The height of the organic compound layer 4 from the substrate 2 is greater than the height of the interlayer insulating layer 28 from the substrate 2, whereby it is possible to obtain a photoelectric conversion element having higher photoelectric conversion efficiency for oblique incidence.

An imaging apparatus including a plurality of lenses and the image sensor according to the present invention may be configured. The image sensor included in the imaging apparatus receives light passing through the plurality of lenses, and based on the received light, generates information to be transferred to a signal processing unit.

The photoelectric conversion device may further include a transmission unit for transmitting data to outside the photoelectric conversion device, or a reception unit for receiving data from outside the photoelectric conversion device. The imaging apparatus including the reception unit or the transmission unit may be a network camera that continues to be placed at a single point.

A first exemplary embodiment is described. The following organic compound layer and electrode were prepared on a charge accumulation portion by vacuum-depositing the organic compound layer and the electrode onto an Si substrate by resistance heating in a vacuum chamber. The charge accumulation portion is of an electron accumulation type.

### [Configuration of Element]

Charge accumulation portion/first charge transport layer/photoelectric conversion layer/second charge transport layer/electrode

First charge transport layer (20 nm): exemplary compound C-2
Photoelectric conversion layer (400 nm): exemplary compound A-1 (mass concentration of 50%)

exemplary compound B-5 (mass concentration of 50%)

Second charge transport layer (50 nm): exemplary compound A-1

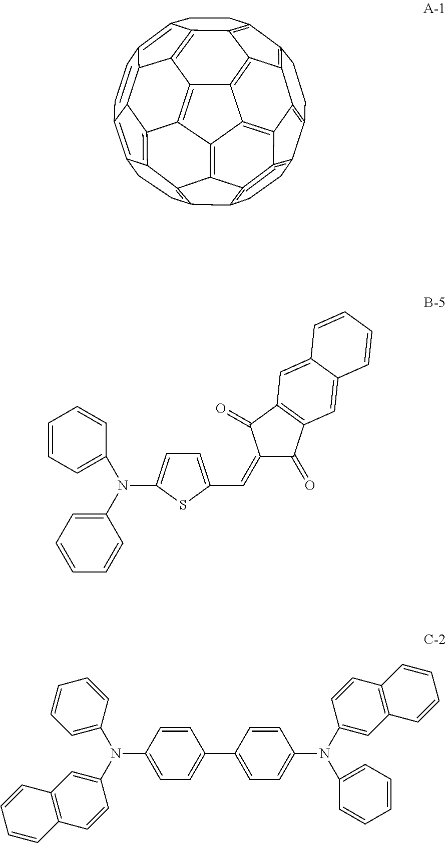

After the charge transport layers were vacuum-deposited, 100 nm of an ITO electrode was formed by sputtering, and then, a protection layer was formed. When the photoelectric conversion characteristics of the prepared element were evaluated, excellent photoelectric conversion characteristics were obtained.

A second exemplary embodiment is described. 400 nm of only the photoelectric conversion layer prepared in the first exemplary embodiment was vacuum-deposited onto a glass substrate. Even when left in the atmosphere, the photoelectric conversion layer formed an excellent amorphous film. The glass-transition temperature of the exemplary compound B-5 of the photoelectric conversion layer used in the exemplary embodiment was 93° C. when measured by differential scanning calorimetry analysis.

A third exemplary embodiment is described. 20 nm of the exemplary compound A-1 of the photoelectric conversion layer prepared in the first exemplary embodiment was vacuum-deposited onto a glass substrate. The ionization potential measured by atmospheric photoelectron spectroscopy (AC-3) was 6.5 eV. This value was larger than the valence band level of Si, which was a charge accumulation portion.

A fourth exemplary embodiment is described. An element was prepared similarly to the first exemplary embodiment, except that a charge accumulation portion of a hole accumulation type was provided in the Si substrate in the first exemplary embodiment, and an organic compound layer had the following configuration.

### [Configuration of Element]

Charge accumulation portion/first charge transport layer/photoelectric conversion layer/second charge transport layer/electrode

First charge transport layer (20 nm): exemplary compound A-1
photoelectric conversion layer (400 nm): exemplary compound A-1 (mass concentration of 70%)

exemplary compound B-5 (mass concentration of 30%)

Second charge transport layer (50 nm): exemplary compound C-2

When the photoelectric conversion characteristics of the prepared element were evaluated, excellent photoelectric conversion characteristics were obtained.

A fifth exemplary embodiment is described. 20 nm of the exemplary compound C-2 of the first electron transport layer prepared in the first exemplary embodiment was vacuum-deposited onto a glass substrate. The ionization potential was measured by atmospheric photoelectron spectroscopy (AC-3). Further, the optical band gap obtained from the absorption ends of the ultraviolet (UV) absorption spectrum was measured, and the LUMO energy level was calculated using the two values. The LUMO energy level was 2.6 eV and smaller than the conduction band level of Si, which was a charge accumulation portion.

As described above, the present disclosure can provide a photoelectric conversion device for reducing noise, thereby having high sensitivity.

According to the present disclosure, it is possible to provide a photoelectric conversion device for reducing noise, thereby having high photoelectric conversion efficiency.

While the present disclosure has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2016-087316, filed Apr. 25, 2016, No. 2016-133394, filed Jul. 5, 2016, and No. 2017-037708, filed Feb. 28, 2017 which are hereby incorporated by reference herein in their entirety.

What is claimed is:

1. A photoelectric conversion device comprising:
a semiconductor substrate including a signal output portion;
an electrode;
an organic compound layer disposed between the signal output portion and the electrode;
a gate electrode configured to transfer a charge; and
floating diffusion configured to accumulate a charge,
wherein the signal output portion is in contact with the organic compound layer.

2. The photoelectric conversion device according to claim 1, wherein the semiconductor substrate includes a p-type portion, an n-type portion, and a p-type portion joined in order, or an n-type portion, a p-type portion, and an n-type portion joined in order, from the organic compound layer side.

3. The photoelectric conversion device according to claim 1, wherein the semiconductor substrate is connected to a correlated double sampling (CDS) circuit.

4. The photoelectric conversion device according to claim 1, wherein the organic compound layer forms an amorphous layer.

5. The photoelectric conversion device according to claim 1, wherein a glass-transition temperature of an organic compound included in the organic compound layer is 80° C. or more.

6. The photoelectric conversion device according to claim 1, wherein a compound included in the organic compound layer is bonded to the signal output portion.

7. The photoelectric conversion device according to claim 1, wherein the organic compound layer includes a photoelectric conversion layer and a first charge transport layer, the first charge transport layer being placed between the photoelectric conversion layer and the signal output portion.

8. The photoelectric conversion device according to claim 7, wherein a compound included in the first charge transport layer is chemically bonded to the signal output portion.

9. The photoelectric conversion device according to claim 7, wherein the photoelectric conversion layer includes an electron-donating compound and an electron-withdrawing compound.

10. The photoelectric conversion device according to claim 9, wherein the electron-withdrawing compound is a C60 derivative or a C70 derivative.

11. The photoelectric conversion device according to claim 1, wherein a lowest unoccupied molecular orbital (LUMO) energy level of the organic compound layer is lower than a conduction band level of the signal output portion.

12. The photoelectric conversion device according to claim 7, wherein an LUMO energy level of the first charge transport layer is lower than a conduction band level of the signal output portion.

13. The photoelectric conversion device according to claim 1, wherein the organic compound layer includes a photoelectric conversion layer and a second charge transport layer, the second charge transport layer being disposed between the photoelectric conversion layer and the electrode.

14. The photoelectric conversion device according to claim 1, wherein a highest occupied molecular orbital (HOMO) energy level of the organic compound layer is higher than a valence band level of the signal output portion.

15. The photoelectric conversion device according to claim 13, wherein a HOMO energy level of the second charge transport layer is higher than a work function of the electrode.

16. The photoelectric conversion device according to claim 1, further comprising an interlayer insulating layer, the interlayer insulating layer being placed between the organic compound layer and another organic compound layer,
wherein a height of the organic compound layer from the semiconductor substrate is equal to or greater than a height of the interlayer insulating layer from the semiconductor substrate.

17. The photoelectric conversion device according to claim 1, further comprising another organic compound layer configured to photoelectrically convert light of a different wavelength from the organic compound layer, the organic compound layer and the other organic compound layer being laminated.

18. An image sensor comprising:
the photoelectric conversion device according to claim 1;
a reading circuit connected to the photoelectric conversion device; and
a signal processing unit connected to the reading circuit.

19. An imaging apparatus comprising:
a plurality of lenses; and
an image sensor configured to receive light passing through the plurality of lenses,
wherein the image sensor is the image sensor according to claim 18.

20. The imaging apparatus according to claim 19, further comprising a transmission unit configured to transmit information to outside the imaging apparatus, or a reception unit configured to receive information from outside the imaging apparatus.
